(19) United States
(12) Patent Application Publication
(10) Pub. No.: US 2021/0385937 A1
(43) Pub. Date: Dec. 9, 2021

(54) INSERT-MOLDED ELECTRONIC MODULES USING THERMALLY CONDUCTIVE POLYCARBONATE AND MOLDED INTERLOCKING FEATURES

(71) Applicant: Covestro LLC, Pittsburg, PA (US)

(72) Inventors: James M. Lorenzo, Mars, PA (US); Jessee McCanna, Midland, PA (US)

(21) Appl. No.: 17/283,098

(22) PCT Filed: Oct. 2, 2019
(86) PCT No.: PCT/US2019/054239

§ 371 Date: Apr. 6, 2021

Related U.S. Application Data
(60) Provisional application No. 62/743,259, filed on Oct. 9, 2018.

(51) Int. Cl. H05K 1/02

(52) U.S. Cl. CPC H05K 1/021; H05K 2203/1327; H05K 2201/10106; H05K 2201/0129

(57) ABSTRACT

Disclosed are insert-molded electronic modules that include an electrical/electronic component and a heat sink that interlocks with, and optionally also encapsulates, the electrical/electronic component to provide thermal management for the component. The heat sink is formed using a thermally conductive thermoplastic polymer composition and replaces the potting compound and thermal interface material typically used in such assemblies. The electrical/electronic component includes openings that allow the thermally conductive thermoplastic polymer composition to flow therethrough and interlock with the electrical/electronic component. The electronic module may include an insert positioned between the electrical/electronic component and the heat sink, wherein the insert includes holes that allow the conductive thermoplastic polymer composition to flow therethrough and interlock with the insert.

### FIELD OF THE INVENTION

The present invention relates in general to electronics and heat sinks, and more specifically to an insert-molded electronic module having an electrical/electronic component integrated with a heat sink with molded interlocking features.

### BACKGROUND OF THE INVENTION

State of the art light emitting diode (LED) light bulbs and other electronics contain printed circuit boards and various electronic components which must be electrically isolated from user contact. These devices must also have sufficient thermal management to keep operating temperatures below a critical value to extend service life; Current high power LEDs produce a significant heat output as up to 60% of the electric power input is converted to heat.

Although there are many different designs for thermal management in such electronic devices, the major heat dissipation route for the heat produced by such electronics is usually through the base to which the electronic device is mounted, or through additional metal heat sinks positioned below the base. For example, one approach for dissipating heat from LEDs mounted on a printed circuit board (i.e., base) is to use a printed circuit board comprising a metal core as compared to traditional printed circuit boards comprising a dielectric core. While metal core printed circuit boards are effective for dissipating heat, disadvantages include increased costs and processing difficulties. In addition, since there are limitations to the size of metal core printed circuit boards, they are more difficult to incorporate into larger sized devices.

Another approach is to attach the LEDs directly to a heat sink using a thermally conductive adhesive or tape. A major disadvantage of this approach it is a labor-intensive process, resulting in increased costs, and the resulting configuration can be subject to high failure rates.

Yet another approach to dissipating heat from LEDs is to mount the LED on a front side of the printed circuit board, and a heat sink on the back side of the board. Such solutions generally require use of a thermal interface material between the printed circuit board and the heat sink to fill the air gap and for better thermal conduction. In general, thermal conduction from such materials is low and thus presents a bottleneck in heat conduction from the board to the heat sink.

Accordingly, a need continues to exist in the art for further improvements to materials and molding methods for use in thermal management in electronic devices that produce heat, such as LED lamps.

### SUMMARY OF THE INVENTION

Accordingly, the present invention provides an insert-molded electronic module comprising a thermally conductive thermoplastic polymer composition as a heat sink to provide thermal management for an electrical/electronic component, wherein the heat sink interlocks with and, optionally, surrounds all or a portion of the electrical/electronic component, thus replacing the potting compound and thermal interface material typically used in such assemblies. The electrical/electronic component includes openings that allow the conductive thermoplastic polymer composition to flow therethrough and interlock with the electrical/electronic component. The electronic module may include an insert positioned between the electrical/electronic component and the heat sink, wherein the insert includes holes that allow the conductive thermoplastic polymer composition to flow therethrough and interlock with the insert.

These and other advantages and benefits of the present invention will be apparent from the Detailed Description of the Invention herein below.

### BRIEF DESCRIPTION OF THE FIGURES

The present invention will now be described for purposes of illustration and not limitation in conjunction with the figures, wherein:

FIG. 1 shows a cross-sectional view of a prior art printed circuit board attached to a heat sink by screws positioned through holes in the board;

FIG. 2A shows a top view of an exemplary inventive electronic module of the present invention containing a heat sink made of a thermally conductive thermoplastic polymer interlocking with a printed circuit board;

FIG. 2B shows a side view of the exemplary inventive electronic module shown in FIG. 2A;

FIG. 3 shows a perspective view of an exemplary inventive electronic module of the present invention containing a heat sink made of a thermally conductive thermoplastic polymer interlocking with a printed circuit board;

FIG. 4 shows a perspective view of an exemplary inventive electronic module of the present invention containing a heat sink made of a thermally conductive thermoplastic polymer interlocking with an insert and a printed circuit board;

FIG. 5 shows a perspective view of an exemplary inventive electronic module of the present invention containing a heat sink made of a thermally conductive thermoplastic polymer interlocking with a printed circuit board;

FIG. 6 shows a perspective view of a cross of the electronic module of FIG. 5 taken along line 6-6;

FIG. 7 shows a side view of the cross-section of FIG. 6;

FIG. 8 shows a perspective view of an exemplary inventive electronic module of the present invention containing a heat sink made of a thermally conductive thermoplastic polymer interlocking with an insert and a printed circuit board;

FIG. 9 shows a perspective view of a cross of the electronic module of FIG. 8 taken along line 9-9; and

FIG. 10 shows a side view of the cross-section of FIG. 9.

### DETAILED DESCRIPTION OF THE INVENTION

The present invention will now be described for purposes of illustration and not limitation. Except in the operating examples, or where otherwise indicated, all numbers expressing quantities, percentages, and so forth in the specification are to be understood as being modified in all instances by the term “about.”

“Interlocking” as used in the context of the present description means that a material at least partially and perhaps fully, enters into a channel, hole, port, bore, or crevice of a component of the assembly. In the case of a printed circuit board, for example, the material may be a heat sink material that may enter through screw holes, through-holes, and/or vertical interconnect access (VIA) holes to interlock the electrical/electronic component, preferably the printed circuit board, to the heat sink. Exemplary printed circuit boards include metal core printed circuit boards, as well as printed circuit boards formed of laminates and dielectric materials, such as polytetrafluoroethylene (Teflon), FR-2 (phenolic cotton paper), FR-3 (cotton paper and epoxy), FR-4 (woven glass and epoxy), FR-5 (woven glass and epoxy), FR-6 (matte glass and polyester), G-10 (woven glass and epoxy), CEM-1 (cotton paper and epoxy), CEM-2 (cotton paper and epoxy), CEM-3 (non-woven glass and epoxy), CEM-4 (woven glass and epoxy), and CEM-5 (woven glass and polyester). Preferable printed circuit boards include metal core boards and FR-4 boards.

“Encapsulate” as used in the context of the present description means that a material at least partially and perhaps fully surrounds a component of the assembly. It does not necessarily mean that a component is hermetically sealed against the environment, but it may have such a meaning. In the case of an electronic module made of a thermally conductive thermoplastic polymer composition, the heat sink “encapsulates” preferably means that the electrical/electronic component, such as an LED light source together with an LED printed circuit board, is surrounded by the thermally conductive thermoplastic polymer composition on at least a bottom portion of the electric/electronic component, and optionally also on one or more sides (e.g., opposing lateral sides) and a small region on the top side of the electric/electronic component, while the electric/electronic component may be open at the top to permit electrical connections for example. That is, the heat sink may surround the electric/electronic component on the lateral sides and preferably on the lower side, but not necessarily on the upper side, preferably not on the upper side.

“Forming the module” as used in the context of the present description means that the thermally conductive thermoplastic polymer composition partly or fully interlocks with, and optionally surrounds or encapsulates, an electrical/electronic component, thus having a joining function. In case of the exemplified printed circuit board, the thermally conductive thermoplastic polymer composition preferably passed through openings in the printed circuit board to interlock the heat sink with the board. The thermally conductive thermoplastic polymer composition may also encapsulate the electrical/electronic component, such as the printed circuit board.

The present invention provides an electronic module comprising an electrical/electronic component and a heat sink, wherein the heat sink comprises a thermally conductive thermoplastic polymer composition. The electrical/electronic component comprises openings that provide entry, passage, or flow of the thermally conductive thermoplastic polymer composition so that the electrical/electronic component may interlock with the heat sink. As such, the heat sink partially or fully interlocks with the electrical/electronic component and optionally, partially or fully surrounds the electrical/electronic component. Some or all of the openings of the electrical/electronic component may become interlocked with the heat sink.

The electronic module may comprise an insert positioned between the heat sink and the electrical/electronic component. The insert may include holes that may provide entry or flow of the thermally conductive thermoplastic polymer composition so that the insert may interlock with the heat sink. According to certain aspects, the holes in the insert may align with the openings in the electrical/electronic component to form a single continuous channel from a bottom side of the insert to a top side of the electrical/electronic component, wherein a top side of the insert contacts a bottom side of the electrical/electronic component. In this way, the thermally conductive thermoplastic polymer composition may flow though the single channel to interlock the insert and the electrical/electronic component with the heat sink.

The insert may be sized to cover at least 100% of the bottom surface of the electrical/electronic component (i.e., may have a length and a width substantially the same as that of the electrical/electronic component). The insert may be larger than the electrical/electronic component, such that the length and width of the insert are greater than the length and width of the electrical/electronic component. For example, the insert may be substantially flat, and may have a length and a width that are individually at least 100% the length and width, respectively, of the electrical/electronic component, such as at least 110%, 120%, 130%, 140%, 150%, 160%, 170%, 180%, 190%, 200%, 220%, 250%, or greater.

The insert may comprise a thermally conductive metal or metal alloy. According to certain aspects, the insert may be aluminum.

When an insert is included in the electronic module of the present invention, the heat sink may encapsulate or surround at least a bottom portion of the insert. According to certain aspects, the heat sink may encapsulate the bottom portion of the insert and one or more lateral sides of the insert. According to certain aspects, the heat sink may encapsulate the bottom portion of the insert and one or more lateral sides of the insert, and may also encapsulate one or more lateral sides of the electrical/electronic component. According to certain aspects, the heat sink may encapsulate the bottom portion of the insert as well as one or more lateral sides of the insert, and may encapsulate one or more lateral sides of the electrical/electronic component as well as regions on the top side of the electrical/electronic component.

The electrical/electronic component may be selected from the group consisting of a printed circuit board, a light emitting diode (LED), a resistor, a constant current driver, a driver/controller, a capacitor, a microprocessor, an integrated circuit, a photocell, a piezo-transducer, an inductor, and a proximity switch. According to a preferred embodiment, the electrical/electronic component comprises a printed circuit board, such as an LED circuit board.

According to certain aspects, the printed circuit board may be a metal core board or a laminated circuit boards such as an FR-4 circuit board. Preferably, the printed circuit board has a thickness of greater than 50 microns (0.05 millimeters), such as greater than 0.1 millimeters, or greater than 0.2 millimeters, or greater than 0.3 millimeters, or greater than 0.4 millimeters, or greater than 0.5 millimeters, or greater than 1.0 millimeters, or greater than 1.5 millimeters, or greater than 2 millimeters.

The openings in the electrical/electronic component may be standard openings, such as attachment openings (e.g., screw holes), through holes, VIAs, or any combination thereof. The openings may further include holes made specifically for entry of the thermally conductive thermoplastic polymer composition to form the electronic modules of the present invention.

The heat sink may include heat dissipation elements such as fins. The fins may extend linearly from a base portion of the heat sink and may provide additional air flow therethrough to aid in heat dissipation from the heat sink. The fins may be positioned on a side of the heat sink opposite from the electrical/electronic component.

The present invention further provides a process of making an electronic module comprising partially or fully interlocking an electrical/electronic component with a heat sink, and optionally surrounding or encapsulating the electrical/electronic component with the heat sink, wherein the heat sink comprises the thermally conductive thermoplastic polymer.

The present invention further yet provides a method of making an electronic module having an integrated heat sink, wherein the method comprises inserting an electrical/electronic component into a mold; introducing the thermally conductive thermoplastic polymer composition into the mold so that the thermally conductive thermoplastic polymer passes through one or more openings on the electrical/electronic component and, optionally, partially or fully surrounds the electrical/electronic component; and cooling the thermally conductive thermoplastic polymer to form the electronic module having the integrated heat sink.

The mold may include cavities positioned above the openings on the electrical/electronic component so that the thermally conductive thermoplastic polymer composition forms caps over the openings.

According to certain aspects, an insert may be positioned beneath the electric/electronic component in the mold, wherein the insert comprises holes configured to allow the thermally conductive thermoplastic polymer composition to pass therethrough and secure the insert to the electronic module with the integrated heat sink.

The methods and modules disclosed herein eliminate the need for a potting compound, a thermal interface material, and fasteners or adhesives in the production of electronic modules, such as an electronic module useful as an LED lamp.

The thermally conductive thermoplastic polymer useful in the present invention may be made from an amorphous thermoplastic polymer or from a blend of an amorphous thermoplastic polymer and a semicrystalline thermoplastic polymer or from a blend of an amorphous thermoplastic polymer and a rubber, such as acrylonitrile-butadiene-styrene (ABS) or styrene-acrylonitrile copolymer (SAN). Such blends are commercially available from Covestro LLC under the BAYBLEND tradename.

Suitable amorphous thermoplastic polymers within the meaning of this invention are, in particular, amorphous polycarbonates, amorphous polyesters and amorphous polyolefins as well as, copolymers and polymer blends thereof. Amorphous polyolefins include both open-chain polyolefins such as polypropylene as well as cyclic olefin copolymers. Preferred as amorphous thermoplastic polymers in the context of the present invention are polycarbonate, polymethylmethacrylate (PMMA) and polystyrene, with polycarbonate being particularly preferred.

Amorphous and semicrystalline thermoplastics may be blended into a resin composition useful in the present invention. Examples of blends of amorphous and semicrystalline thermoplastics are well known to those skilled in the art. Some examples of such blends are polycarbonate and polyethylene terephthalate, polycarbonate and polybutylene terephthalate, polycarbonate and polyphenylene sulfide, polycarbonate and), liquid crystalline polymers. Some of these blends are commercially available from Covestro LLC under the trade name MAKROBLEND. There is no limitation on what kind of amorphous thermoplastic to blend with what kind of semicrystalline thermoplastic as long as the resulted blend serves the intended application.

Semicrystalline thermoplastic polymers and methods of their production are known to those skilled in the art. Preferred semicrystalline thermoplastic polymers for use in the inventive composition include, but are not limited to, polyethylene, polypropylene, polybutylene terephthalate and polyethylene terephthalate, polyphenylene sulfide, polyphenylene either, liquid crystalline polymers, and polyamide.

Where present in a blend, the semicrystalline thermoplastic polymer may be present in an amount ranging from 90% to 30% of the composition useful in the present invention, more preferably from 80% to 40% and most preferably from 70% to 50%. The semicrystalline thermoplastic polymer may be present in the composition useful in the present invention in an amount ranging between any combinations of these values, inclusive of the recited values.

The inventive process involves injection molding a heat sink component using a thermally conductive thermoplastic polymer composition, preferably a material such as MAKROLON TC8030, a polycarbonate commercially available from Covestro LLC. The electrical/electronic component is inserted into a mold and the thermally conductive thermoplastic polymer composition is molded around it to form a heat sink. The electrical/electronic component includes openings, such as attachment holes (e.g., screw holes), through holes, VIAs, and any combination thereof that allow the thermally conductive thermoplastic polymer composition to pass therethrough and interlock the electrical/electronic component to the heat sink.

The mold may include cavities positioned above the openings on the electrical/electronic component so that the thermally conductive thermoplastic polymer composition forms caps over the openings.

An insert may be position beneath the electrical/electronic component in the mold, wherein the insert may include holes that allow the thermally conductive thermoplastic polymer composition to pass therethrough and interlock the insert to the heat sink. According to certain aspects, the holes in the insert may align with the openings in the electric/electronic component so that the thermally conductive thermoplastic polymer composition may pass or flow through the aligned holes/openings and interlock the electric/electronic component and insert to the heat sink.

The heat sink may contain features, holes or undercuts to act as a joint with mechanical interlock to allow connection to a housing, or further reaction injection molded components to better bond to the heat sink.

According to certain aspects, the heat sink component may be subsequently inserted into a mold designed for reaction injection molded (RIM) of further components. Additional electronics such as an LED driver/controller board may be inserted into a cavity in the heat sink. RIM material, such as polyurethane or another thermoplastic, may be injected into the cavity, filling the lower portion of the heat sink encapsulating the electrical/electronic component and replacing the potting material currently used for metal heat sinks. After filling the lower cavity in the heat sink, the thermoplastic may continue to fill the mold, forming a further assembly, such as the base of an LED bulb which terminates in a traditional “Edison” style screw-in base.

Thermally conductive polycarbonate is commercially available for example from Covestro LLC under names MAKROLON TC8060 and TC8030. These materials, which contain polycarbonate and expanded graphite, are particularly preferred in the practice of the present invention and are described in greater detail in U.S. Published Patent Application No. 2012/0319031, the entire contents of which are incorporated by reference herein. The compositions provided in the '031 application contain from 90 wt.-% to 30 wt.-% of at least one amorphous thermoplastic or at least one semi crystalline thermoplastic or a mixture thereof and 10 wt.-% to 70 wt.-% of expanded graphite, wherein 90 wt.-% of the particles of the expanded graphite have a particle size of at least 200 microns. As those skilled in the art will appreciate, other thermally conductive polymers may also be used.

Suitable polycarbonate resins for preparing the composition useful in the present invention are homopolycarbonates and copolycarbonates, both linear or branched resins and mixtures thereof. As used herein, the term “polycarbonate” includes homopolycarbonates such as BPA polycarbonate, copolycarbonates derived from two or more different dihydric phenols, and copolyestercarbonates which include structural units derived from one or more dihydric phenols and one or more diacid derived structural units. The diacid, for example, includes dodecandioic acid, terephthalic acid, isophthalic acid. U.S. Pat. No. 4,983,706 describes a method for making copolyestercarbonate.

The polycarbonates have a weight average molecular weight (as determined by gel permeation chromatography, or size-exclusion chromatography) of preferably 10,000 to 200,000 g/mol, more preferably 20,000 to 80,000 g/mol and their melt flow rate, per ASTM D-1238 at 300° C. and 1.2 kg weight, is preferably 1 to 80 g/10 min, more preferably 20 to 65 g/10 min. Such polycarbonates may be prepared, for example, by the known diphasic interface process from a carbonic acid derivative such as phosgene and dihydroxy compounds by polycondensation (See, German Offenlegungsschriften 2,063,050; 2,063,052; 1,570,703; 2,211,956; 2,211,957 and 2,248,817; French Patent 1,561,518; and the monograph by H. Schnell, “Chemistry and Physics of Polycarbonates”, Interscience Publishers, New York, N.Y., 1964).

In the present context, dihydroxy compounds suitable for the preparation of the polycarbonates useful in the invention conform to the structural formulae (1) or (2) below.

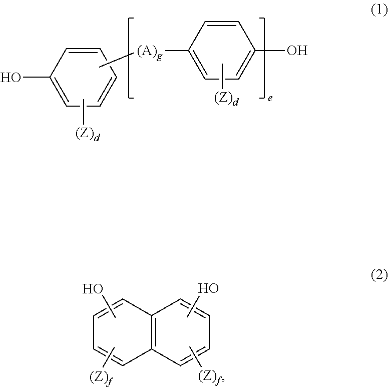

wherein, A denotes an alkylene group with 1 to 8 carbon atoms, an alkylidene group with 2 to 8 carbon atoms, a cycloalkylene group with 5 to 15 carbon atoms, a cycloalkylidene group with 5 to 15 carbon atoms, a carbonyl group, an oxygen atom, a sulfur atom, —SO— or —SO₂ or a radical conforming to

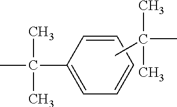

wherein, e and g both denote the number 0 to 1; Z denotes F, Cl, Br or C₁-C₄-alkyl and if several Z radicals are substituents in one aryl radical, they may be identical or different from one another; d denotes an integer of from 0 to 4; and f denotes an integer of from 0 to 3.

Among the dihydroxy compounds useful in the practice of the present invention are hydroquinone, resorcinol, bis-(hydroxyphenyl)-alkanes, bis-(hydroxy-phenyl)-ethers, bis-(hydroxyphenyl)-ketones, bis-(hydroxy-phenyl)-sulfoxides, bis-(hydroxyphenyl)-sulfides, bis-(hydroxyphenyl)-sulfones, and α,α-bis-(hydroxyphenyl)-diisopropylbenzenes, as well as their nuclear-alkylated compounds. These and further suitable aromatic dihydroxy compounds are described, for example, in U.S. Pat. Nos. 5,401,826; 5,105,004; 5,126,428; 5,109,076; 5,104,723; 5,086,157; 3,028,356; 2,999,835; 3,148,172; 2,991,273; 3,271,367; and 2,999,846, the entire contents of which are incorporated herein by reference.

Further examples of suitable bisphenols are 2,2-bis-(4-hydroxyphenyl)-propane (bisphenol A), 2,4-bis-(4-hydroxyphenyl)-2-methyl-butane, 1,1-bis-(4-hydroxyphenyl)-cyclohexane, α,α-bis-(4-hydroxy-phenyl)-p-diisopropylbenzene, 2,2-bis-(3-methyl-4-hydroxyphenyl)-propane, 2,2-bis-(3-chloro-4-hydroxyphenyl)-propane, 4,4′-dihydroxy-diphenyl, bis-(3,5-dimethyl-4-hydroxyphenyl)-methane, 2,2-bis-(3,5-dimethyl-4-hydroxyphenyl)-propane, bis-(3,5-dimethyl-4-hydroxyphenyl)-sulfide, bis-(3,5-dimethyl-4-hydroxy-phenyl)-sulfoxide, bis-(3,5-dimethyl-4-hydroxyphenyl)-sulfone, dihydroxy-benzophenone, 2,4-bis-(3,5-dimethyl-4-hydroxyphenyl)-cyclohexane, α,α-bis-(3,5-dimethyl-4-hydroxyphenyl)-p-diisopropyl-benzene and 4,4′-sulfonyl diphenol.

Examples of particularly preferred aromatic bisphenols are 2,2-bis-(4-hydroxyphenyl)-propane, 2,2-bis-(3,5-dimethyl-4-hydroxyphenyl)-propane, 1,1-bis-(4-hydroxyphenyl)-cyclohexane and 1,1-bis-(4-hydroxy-phenyl)-3,3,5-trimethylcyclohexane. The most preferred bisphenol is 2,2-bis-(4-hydroxyphenyl)-propane (bisphenol A).

The polycarbonates useful in the invention may entail in their structure units derived from one or more of the suitable bisphenols. Among those resins suitable in the practice of the invention are phenolphthalein-based polycarbonate, copolycarbonates and terpolycarbonates such as are described in U.S. Pat. Nos. 3,036,036 and 4,210,741, both of which are incorporated by reference herein.

The polycarbonates useful in the present invention may also be branched by condensing therein small quantities, e.g., 0.05 to 2.0 mol % (relative to the bisphenols) of polyhydroxyl compounds. Polycarbonates of this type have been described, for example, in German. Offenlegungsschriften 1,570,533; 2,116,974 and 2,113,374; British Patents 885,442 and 1,079,821 and U.S. Pat. No. 3,544,514, which is incorporated herein by reference. The following are some examples of polyhydroxyl compounds which may be used for this purpose: phloroglucinol; 4,6-dimethyl-2,4,6-tri-(4-hydroxyphenyl)-heptane; 1,3,5-tri-(4-hydroxyphenyl)-benzene; 1,1,1-tri-(4-hydroxyphenyl)-ethane; tri-(4-hydroxyphenyl)-phenyl-methane; 2,2-bis-[4,4-(4,4′-dihydroxydiphenyl)]-cyclohexyl-propane; 2,4-bis-(4-hydroxy-1-isopropylidine)-phenol; 2,6-bis-(2′-dihydroxy-5′-methylbenzyl)-4-methyl-phenol; 2,4-dihydroxybenzoic acid; 2-(4-hydroxy-phenyl)-2-(2,4-dihydroxyphenyl)-propane and 1,4-bis-(4,4′-dihydroxy-triphenylmethyl)-benzene. Some of the other polyfunctional compounds are 2,4-dihydroxy-benzoic acid, trimesic acid, cyanuric chloride and 3,3-bis-(4-hydroxyphenyl)-2-oxo-2,3-dihydroindole.

In addition to the polycondensation process mentioned above, other processes for the preparation of the polycarbonates of the invention are polycondensation in a homogeneous phase and transesterification. The suitable processes are disclosed in U.S. Pat. Nos. 3,028,365; 2,999,846; 3,153,008; and 2,991,273 which are incorporated herein by reference.

The preferred process for the preparation of polycarbonates is the interfacial polycondensation process. Other methods of synthesis in forming the polycarbonates of the invention, such as disclosed in U.S. Pat. No. 3,912,688, incorporated herein by reference, may be used. Suitable polycarbonate resins are available in commerce, for instance, from Covestro LLC under the MAKROLON trademark.

The term polyester as used herein is meant to include homo-polyesters and co-polyesters resins. These are resins the molecular structure of which include at least one bond derived from a carboxylic acid, preferably excluding linkages derived from carbonic acid. These are known resins and may be prepared through condensation or ester interchange polymerization of the diol component with the diacid according to known methods. Suitable resins include poly(alkylene dicarboxylates), especially poly(ethylene terephthalate) (PET), poly(1,4-butylene terephthalate) (PBT), poly(trimethylene terephthalate) (PTT), poly(ethylene naphthalate) (PEN), poly(butylenes naphthalate) (PBN), poly(cyclohexanedimethanol terephthalate) (PCT), poly(cyclohexanedimethanol-co-ethylene terephthalate) (PETG or PCTG), and poly(1,4-cyclohexanedimethyl-1,4-cyclohexanedicarboxylate) (PCCD).

U.S. Pat. Nos. 2,465,319, 3,953,394 and 3,047,539, all incorporated herein by reference herein, disclose suitable methods for preparing such resins. The suitable polyalkylene terephthalates are characterized by an intrinsic viscosity of at least 0.2 and preferably at least 0.4 deciliter/gram as measured by the relative viscosity of an 8% solution in orthochlorophenol at 25° C. The upper limit is not critical but it preferably does not exceed 2.5 deciliters/gram. Especially preferred polyalkylene terephthalates are those with an intrinsic viscosity in the range of 0.4 to 1.3 deciliter/gram.

The alkylene units of the polyalkylene terephthalates which are suitable for use in the present invention contain from 2 to 5, preferably 2 to 4 carbon atoms. Polybutylene terephthalate (prepared from 1,4-butanediol) and polyethylene terephthalate are the preferred tetraphthalates for use in the present invention. Other suitable polyalkylene terephthalates include polypropylene terephthalate, polyisobutylene terephthalate, polypentyl terephthalate, polyisopentyl terephthalate, and polyneopentyl terephthalate. The alkylene units may be straight chains or branched chains.

The preferred polyalkylene terephthalates may contain, in addition to terephthalic acid groups, up to 20 mol % of groups from other aromatic dicarboxylic acids with 8 to 14 carbon atoms or aliphatic dicarboxylic acids with 4 to 12 carbon atoms, such as groups from phthalic acid, isophthalic acid, naphthalene-2,6-dicarboxylic acid, 4,4′-di-phenyl-dicarboxylic acid, succinic, adipic, sebacic, azelaic acids or cyclohexanediacetic acid. The preferred polyalkylene terephthalates may contain, in addition to ethylene glycol or butanediol-1,4-groups, up to 20 mol % of other aliphatic diols with 3 to 12 carbon atoms or cylcoaliphatic diols with 6 to 21 carbon atoms, e.g., groups from propanediol-1,3,2-ethylpropanediol-1,3, neopentyl glycol, pentanediol-1,5, hexanediol-1,6, cyclohexane-dimethanol-1,4,3-methylpentanediol-2,4,2-methyl-pentanediol-2,4,2,2,4-trimethylpentanediol-1,3, and -1,6,2-ethylhexanediol-1,3,2,2-diethylpropanediol-1,3, hexanediol-2,5,1,4-di-(13-hydroxyethoxy)-benzene, 2,2-bis-(4-hydroxycyclohexyl)-propane, 2,4-dihydroxy-1,1,3,3-tetra-methyl-cyclobutane, 2,2-bis-(3-β-hydroxyethoxyphenyl)-propane and 2,2-bis-(4-hydroxypropoxyphenyl)-propane (DE-OS 24 07 674, 24 07 776, 27 15 932).

The polyalkylene terephthalates may be branched by incorporating relatively small amounts of 3- or 4-hydric alcohols or 3- or 4-basic carboxylic acids, such as are described, for example, in DE-OS 19 00 270 and U.S. Pat. No. 3,692,744. Examples of preferred branching agents comprise trimesic acid, trimellitic acid, trimethylol-ethane and -propane and pentaerythritol. Preferably no more than 1 mol % of branching agent, with respect to the acid component, is used.

Polyalkylene terephthalates prepared solely from terephthalic acid and its reactive derivatives (e.g. its diallyl esters) and ethylene glycol and/or butanediol-1,4 (polyethyleneterephthalate and polybutyleneterephthalate) and mixtures of these polyalkylene terephthalates are particularly preferred.

Suitable polyalkylene terephthalates are disclosed in U.S. Pat. Nos. 4,267,096; 4,786,692; 4,352,907; 4,391,954; 4,125,571; 4,125,572; and 4,188,314, 5,407,994 the disclosures of which are incorporated herein by reference.

The at least one amorphous thermoplastic is present in an amount ranging from 90% to 30% of the composition useful in the present invention, more preferably from 80% to 40% and most preferably from 70% to 50%. The at least one amorphous thermoplastic may be present in the composition of the present invention in an amount ranging between any combination of these values, inclusive of the recited values.

Expanded graphite and methods of its production are known to those skilled in the art. Expanded graphite may present in an amount ranging from 10 wt.-% to 70 wt.-% of the composition useful the present invention, more preferably from 20 wt.-% to 60 wt.-% and most preferably from 30 wt.-% to 50 wt.-%. The expanded graphite may be present in an amount ranging between any combinations of these values, inclusive of the recited values. It is preferred that at least 90% of the particles of the expanded graphite should have a particle size of at least 200 microns. There are also highly thermally conductive expanded graphites commercially available, which have a lower particles size, e.g., where 90% of the particles have a particle size of 100 maximum, which may alternatively be used.

The thermally conductive polycarbonate composition may further include effective amounts of any of the additives known for their function in the context of thermoplastic molding compositions. These include any one or more of lubricants, mold release agents, for example pentaerythritol tetrastearate, nucleating agents, antistatic agents, other antioxidants, thermal stabilizers, light stabilizers, hydrolytic stabilizers, impact modifiers, fillers and reinforcing agents, colorants or pigments, as well as further flame retarding agents, other drip suppressants or a flame retarding synergists. The additives may be used in effective amounts, preferably of from 0.01 to a total of 30 wt.-% relative to the total weight of the polycarbonate component.

The thermally conductive polycarbonate composition may be produced by conventional procedures using conventional equipment. It may be used to produce moldings of any kind by thermoplastic processes such as injection molding, extrusion and blow molding methods.

As known to those in the art, a wide variety of different molded thermoplastic parts may be produced by the reaction injection molding (“RIM”) process. This process involves filling a closed mold with highly reactive liquid starting components within a very short time, generally by using high output, high pressure dosing apparatus after the components have been mixed. The RIM process involves the intimate mixing of a components of the thermoplastic, followed by the injection of this mixture into a mold for subsequent rapid curing. For a thermoplastic such as polyurethane, such as may be used to form housings for the insert-molded electronic modules, the components may include a polyisocyanate components and an isocyanate-reactive component. For example, the polyisocyanate component may preferably be based on a liquid polyisocyanate, and the isocyanate-reactive component may contain a high molecular weight isocyanate-reactive component, preferably a polyol and/or an amine polyether, and may contain a chain extender containing amino and/or hydroxyl groups.

A number of US patents describe various RIM processes, all which are suitable in the practice of the present invention including U.S. Pat. Nos. 4,218,543; 4,433,067; 4,444,910; 4,530,941; 4,774,263; 4,774,264; 4,929,697; 5,003,027; 5,350,778; 5,563,232; 5,585,452; and 5,686,042, the entire contents of which are incorporated by reference herein.

Polyurethanes useful in RIM processes are preferably produced by the reaction at least one relatively high molecular weight hydroxyl-containing polyol, at least one chain extender; and at least one polyisocyanate, polyisothiocyanate or mixture thereof. Suitable polyurethanes are disclosed in U.S. Published Patent Application No. 2016/0084490 to Davis et al., the entire contents of which are incorporated herein.

Other materials which can be included in the reaction mixture included any of the materials generally used in the RIM art. Reinforcing fillers, which allow reduced contraction of the molded product upon cooling, as well as adjustment of tensile modulus and flex modulus, can also be used and are well known in the art. Suitable inorganic fillers include glass in the form of fibers or flakes, mica, wollastonite, carbon black, talc, calcium carbonate, and carbon fibers. Organic fillers, although less preferred, are also suitable.

Other additives which may be used in the present invention include catalysts, especially tin(II) salts of carboxylic adds, dialkyltin salts of carboxylic acids, dialkyltin mercaptides, dialkyltin dithioesters, and tertiary amines. Preferred among these catalysts are dibutyltin dilaurate and 1,4-diazabicyclo[2,2,21]octane (triethylene diamine), especially mixtures of these catalysts. The catalysts are generally used in amounts of 0.01 to 10% (preferably 0.05 to 2%), based on the weight of the high molecular weight component.

It is also possible to use surface-active additives such as emulsifiers and foam stabilizers. Examples include siloxanes, N-stearyl-N′,N′-bis-hydroxyethyl urea, oleyl polyoxyethylene amide, stearyl diethanol amide, isostearyl diethanolamide, polyoxyethylene glycol monoleate, a pentaerythritol/adipic acid/oleic acid ester, a hydroxyethyl imidazole derivative of oleic acid, N-stearyl propylene diamine, and the sodium salts of castor oil sulfonates or of fatty acids. Alkali metal or ammonium salts of sulfonic acid, such as dodecylbenzenesulfonic add or dinaphthylmethanesulfonic acid, and fatty acids may also be used as surface-active additives. Particularly suitable surface-active compounds include polyether siloxanes of the type generally known for use in the polyurethane art, such as water-soluble polyether siloxanes. The structure of these siloxanes is generally such that a copolymer of ethylene oxide and propylene oxide is attached to a polydimethylsiloxane functionality. Methods of manufacturing preferred siloxanes are described in U.S. Pat. No. 4,906,721, the disclosure of which is herein incorporated by reference.

It is also possible to use mold release agents, which are compounds that are added to the reactive components of the isocyanate addition reaction, usually the isocyanate-reactive component, to assist in the removal of a polyurethane product from a mold. Suitable mold release agents for the present invention include those based at least in part on fatty acid esters (e.g., U.S. Pat. Nos. 3,726,952, 3,925,527, 4,058,492, 4,098,731, 4,201,847, 4,254,228, 4,868,224, and 4,954,537 and British Patent 1,365,215); metal and/or amine salts of carboxylic acids, amido carboxylic acids, phosphorus-containing acids, or boron-containing acids (e.g., U.S. Pat. Nos. 4,519,965, 4,581,386, 4,585,803, 4,876,019, 4,895,879, and 5,135,962); polysiloxanes (e.g., U.S. Pat. No. 4,504,313); amidines (e.g., U.S. Pat. Nos. 4,764,540, 4,789,688, and 4,847,307); resins prepared by the reaction of isocyanate prepolymers and a polyamine-polyimine component (e.g., U.S. Pat. No. 5,198,508); neutralized esters prepared from certain amine-started tetrahydroxy compounds described in U.S. Pat. No. 5,208,268; and aliphatic polyalkylene and polyalkadienes. Preferred mold release agents contain zinc stearate.

In addition to the reinforcement fillers, catalysts, surface-active agents, and mold release agents mentioned above, other additives which may be used in the molding compositions of the present invention include known fillers of other types, blowing agents, cell regulators, flame retarding agents, plasticizers, and dyes of the types generally known in the art.

The compositions according to the present invention are suited for processing by the RIM process. In general, in the RIM process, two separate streams are intimately mixed and subsequently injected into a suitable mold, although it is possible to use more than two streams.

In the known RIM process used for carrying out the process according to the present invention, the components may be mixed simultaneously, or the non-reactive components may be pre-mixed and then mixed with the reactive components. A starting temperature of from 10° C. to 70° C., preferably from 30° C. to 50° C. is preferably chosen for the mixture introduced into the mold. The temperature of the mold itself is preferably from 40° C. to 100° C., more preferably from 50° C. to 70° C. After completion of the reaction and molding process, the resultant product is removed from the mold.

### Example

The present invention is further illustrated, but is not to be limited, by the following example, which is depicted in connection with the figures. Although the invention is exemplified in the context of an LED printed circuit board, those skilled in the art will appreciate the applicability of the instant invention to a variety of assemblies containing a variety of electrical/electronic components, including, but not limited to, printed circuit boards, driver/controllers, light emitting diodes (LEDs), resistors, constant current drivers, capacitors, microprocessors, integrated circuits, photocells, piezo-transducers, inductors, and proximity switches. The LED printed circuit board shown in the figures embodies the general idea of the invention. The materials of the heat sink are only specified for the purpose of an example. Those skilled in the art will appreciate that such materials can be varied within the scope of the present invention.

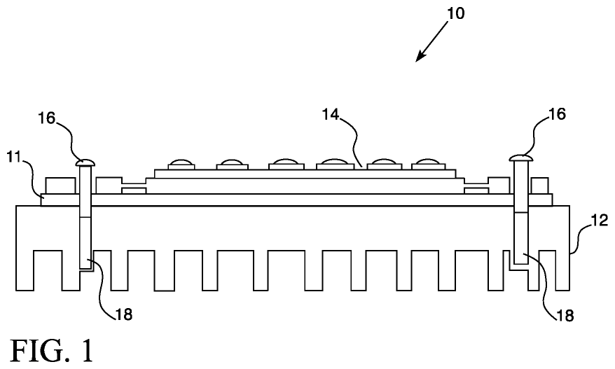

FIG. 1A shows a prior art electronic module 10 wherein an electrical/electronic component 14 is mounted to a heat sink 12 using screws 16 mounted through attachment openings 18 in the electrical/electronic component 14 and the heat sink 12. In order to provide improved contact between the electrical/electronic component 14 and the heat sink 12, a thermal interface material 11 is included.

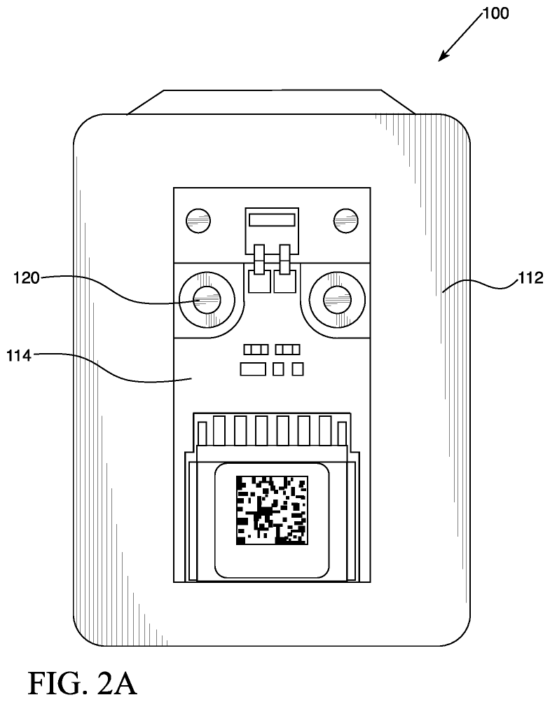

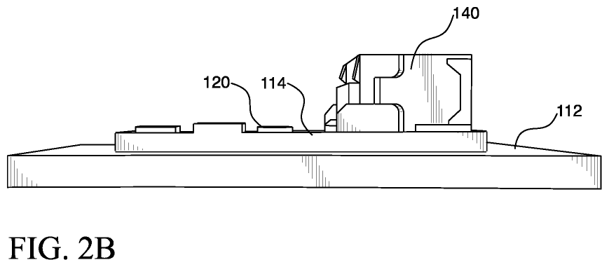

FIG. 2A shows an electronic module 100 of the presently disclosed invention, wherein the electrical/electronic component 114 is encapsulated and interlocked with the heat sink 112. As shown, at least a bottom side of the electrical/electronic component 114 is encapsulated by the thermally conductive thermoplastic polymer composition of the heat sink 112, and attachment openings 120 (e.g., screw holes) are interlocked by the thermally conductive thermoplastic polymer composition of the heat sink 112. FIG. 2B shows a side view of the electronic module of FIG. 2A, wherein the electrical/electronic component 114 includes an LED 140.

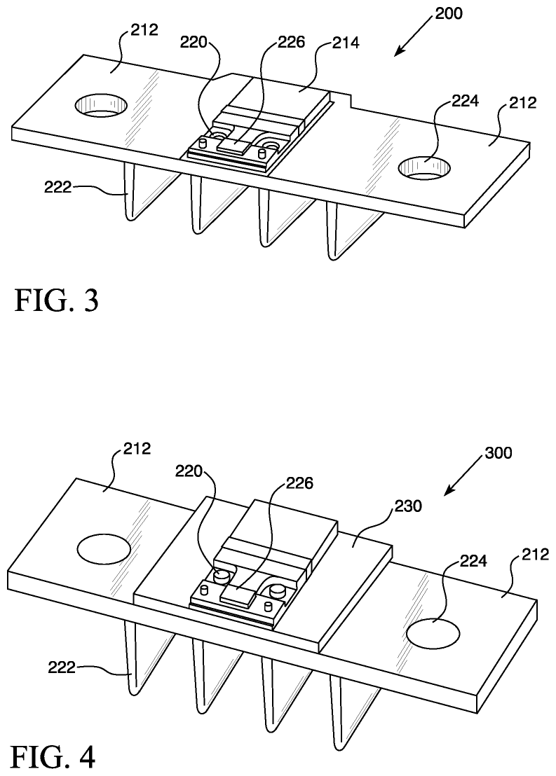

FIG. 3 shows an electronic module 200 comprising an electrical/electronic component 214 encapsulated by a heat sink 212, wherein the electrical/electronic component 214 may include an LED element 226. The heat sink 212 includes laterally extending fins 222, and additional holes or attachment elements 224 that may assist in connection between the electronic module 200 and additional components such as an injection molded housing. Also shown are the interlocking features 220 on the electronic module 200, which include regions of the heat sink wherein the thermally conductive thermoplastic polymer composition has flowed into openings on the electrical/electronic component 214.

FIG. 4 shows an electronic module 300 comprising an electrical/electronic component 214 encapsulated by a heat sink 212, and further including an insert 230 positioned between the electrical/electronic component 214 and the heat sink 212. As in FIG. 3, the heat sink 212 includes laterally extending fins 222, and additional holes or attachment elements 224 that may assist in connection between the electronic module 200 and additional components such as an injection molded housing. Also shown are the interlocking features 220 on the electronic module 300, wherein holes (not shown) in the insert 230 are aligned with the openings on the electrical/electronic component 214 to form continuous channels through which the thermally conductive thermoplastic polymer composition has flowed to form the interlocking features of the electronic module 300. As shown in FIG. 4, at least a bottom side of the insert 230 is encapsulated by the thermally conductive thermoplastic polymer composition of the heat sink 212.

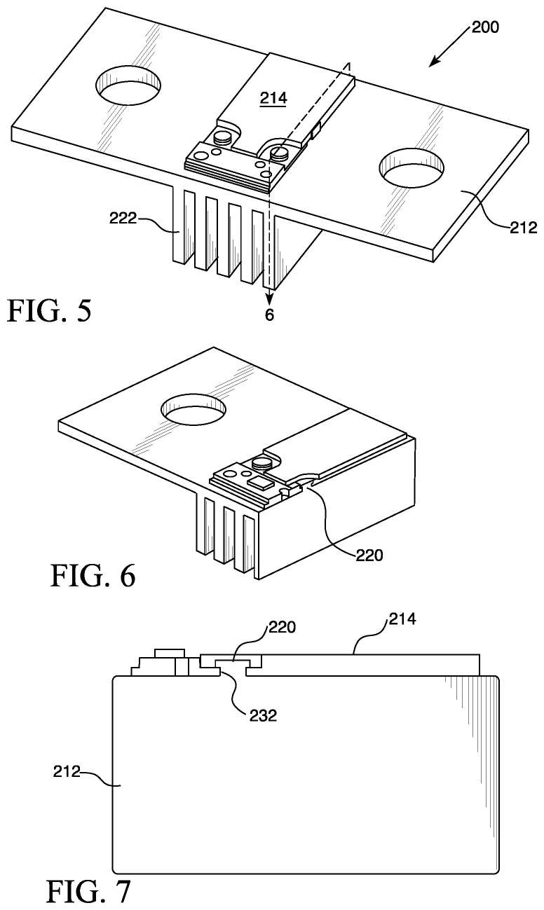

FIGS. 5-7 show another view of an electronic module 200 comprising an electrical/electronic component 214 encapsulated by a heat sink 212 that includes laterally extending fins 222. While the electronic module 200 is shown to include four laterally extending fins 222, any number, size, and arrangement of fins is within the scope of the present invention. Moreover, while various configurations of a heat sink (112, 212) are shown in the figures, these representations are exemplary only and are intended to assist in describing the presently disclosed invention. Other designs and configurations for the heat sink are envisioned and within the scope of the present invention. Shown in FIGS. 6 and 7 are perspective and side views, respectively, of a cross-section of the electronic module 200 taken along line 6-6 from FIG. 5. An interlocking feature 220 on the electronic module 200 is shown, wherein the thermally conductive thermoplastic polymer composition of the heat sink 212 has flowed into an opening 232 in the electrical/electronic component 214.

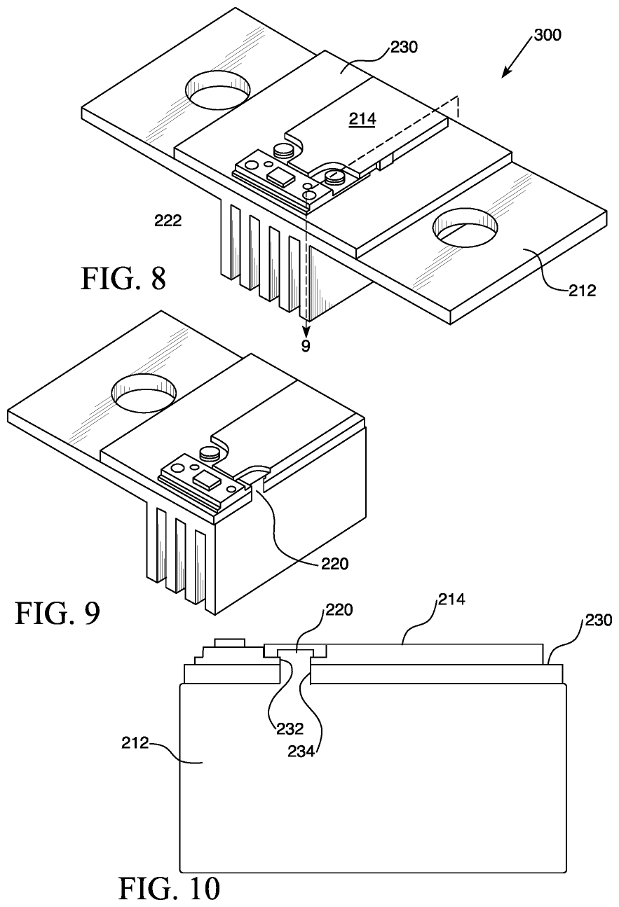

FIGS. 8-10 show another view of an electronic module 300 comprising an electrical/electronic component 214 encapsulated by a heat sink 212, and further including an insert 230 positioned between the electrical/electronic component 214 and the heat sink 212. Shown in FIGS. 9 and 10 are perspective and side views, respectively, of a cross-section of the electronic module 300 taken along line 9-9 from FIG. 8. An interlocking feature 220 on the electronic module 300 is shown, wherein the thermally conductive thermoplastic polymer composition of the heat sink 212 has flowed through a channel formed by alignment of an opening 232 in the electrical/electronic component 214 and a hole 234 in the insert 230.

The foregoing example of the present invention is offered for the purpose of illustration and not limitation. It will be apparent to those skilled in the art that the embodiments described herein may be modified or revised in various ways without departing from the spirit and scope of the invention. The scope of the invention is to be measured by the appended claims.

As for other details of the present invention, materials and alternate related configurations may be employed as within the level of those with skill in the relevant art. The same may hold true with respect to process-based aspects of the invention in terms of additional acts as commonly or logically employed. In addition, though the invention has been described in reference to several examples, optionally incorporating various features, the invention is not to be limited to that which is described or indicated as contemplated with respect to each variation of the invention. Various changes may be made to the invention described and equivalents (whether recited herein or not included for the sake of some brevity) may be substituted without departing from the true spirit and scope of the invention. Such changes or others may be undertaken or guided by the principles of design for assembly.

Also, it is contemplated that any optional feature of the inventive variations described may be set forth and claimed independently, or in combination with any one or more of the features described herein. Reference to a singular item, includes the possibility that there are plural of the same items present. More specifically, as used herein and in the appended claims, the singular forms “a,” “an,” “said,” and “the” include plural referents unless the specifically stated otherwise. In other words, use of the articles allow for “at least one” of the subject item in the description above as well as the claims below. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Without the use of such exclusive terminology, the term “comprising” in the claims shall allow for the inclusion of any additional element—irrespective of whether a given number of elements are enumerated in the claim, or the addition of a feature could be regarded as transforming the nature of an element set forth in the claims. Stated otherwise, unless specifically defined herein, all technical and scientific terms used herein are to be given as broad a commonly understood meaning as possible while maintaining claim validity.

Various aspects of the subject matter described herein are set out in the following numbered clauses:

1. An electronic module comprising: an electrical/electronic component; a heat sink comprising a thermally conductive thermoplastic polymer composition, wherein the heat sink passes through one or more openings on the electrical/electronic component, and optionally partially or fully surrounds the electrical/electronic component, to form the electronic module.

2. The electronic module according to Clause 1, wherein the heat sink surrounds at least a bottom portion of the electrical/electronic component.

3. The electronic module according to Clause 1 or 2, wherein the electrical/electronic component is selected from the group consisting of a printed circuit board, a light emitting diode (LED), a resistor, a constant current driver, a driver/controller, a capacitor, a microprocessor, an integrated circuit, a photocell, a piezo-transducer, an inductor, and a proximity switch.

4. The electronic module according to clause 1 or 2, wherein the electrical/electronic component comprises a printed circuit board, and the openings comprise attachment openings, VIA holes, through-holes, and any combination thereof in the printed circuit board.

5. The electronic module according to clause 4, wherein the printed circuit board has a thickness of greater than 50 microns (0.05 millimeters), or greater than 500 microns (0.5 millimeters).

6. The electronic module according to any one of clauses 1 to 5, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers

7. The electronic module according to any one of clauses 1 to 6, wherein the thermally conductive thermoplastic polymer composition comprises expanded graphite in an amount of from 10 wt.-% to 70 wt.-% of the composition, or from 20 wt.-% to 60 wt.-% of the composition, or from 30 wt.-% to 50 wt.-% of the composition.

8. The electronic module according to clause 7, wherein at least 90% of the particles of the expanded graphite have a particle size of at least 200 microns.

9. The electronic module according to any one of clauses 1 to 8, wherein the heat sink comprises linearly extending fins.

10. The electronic module according to any one of clauses 1 to 9, further comprising an insert positioned between the electrical/electronic component and the heat sink.

11. The electronic module according to clause 10, wherein the heat sink surrounds at least a bottom portion of the insert.

12. The electronic module according to clause 10 or 11, wherein the insert is substantially flat.

13. The electronic module according to any one of clauses 10 to 12, wherein the insert comprises holes for the thermally conductive thermoplastic polymer of the heat sink to pass through to secure the heat sink to the insert.

14. The electronic module according to clause 13, wherein the holes in the heat sink align with the openings in the electric/electronic component so that the thermally conductive thermoplastic polymer of the heat sink secures the insert and the electric/electronic component to the heat sink.

15. The electronic module according to any one of clauses 10 to 14, wherein the insert comprises a thermally conductive metal or metal alloy, such as aluminum.

16. An assembly comprising, the electronic module according to any one of clauses 1 to 15, and further comprising an additional injection molded part that partially or fully surrounds the electronic module.

17. A process for making an electronic module, the process comprising: passing a heat sink through one or more openings on an electrical/electronic component; and optionally, partially or fully surrounding the electrical/electronic component with the heat sink, wherein the heat sink comprises a thermally conductive thermoplastic polymer composition.

18. The process according to clause 17, wherein the heat sink surrounds at least a bottom portion of the electrical/electronic component.

19. The process according to clause 17 or 18, wherein the electrical/electronic component is selected from the group consisting of a printed circuit board, a light emitting diode (LED), a resistor, a constant current driver, a driver/controller, a capacitor, a microprocessor, an integrated circuit, a photocell, a piezo-transducer, an inductor, and a proximity switch

20. The process according to clause 17 or 18, wherein the electrical/electronic component comprises a printed circuit board, and the openings comprise attachment openings, VIA holes, through-holes, and any combination thereof in the printed circuit board.

21. The process according to any one of clauses 17 to 20, wherein the printed circuit board has a thickness of greater than 50 microns (0.05 millimeters), or greater than 500 microns (0.5 millimeters).

22. The process according to any one of clauses 17 to 21, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers

23. The process according to any one of clauses 17 to 22, wherein the thermally conductive thermoplastic polymer composition comprises expanded graphite in an amount of from 10 wt.-% to 70 wt.-% of the composition, or from 20 wt.-% to 60 wt.-% of the composition, or from 30 wt.-% to 50 wt.-% of the composition.

24. The process according to clause 23, wherein at least 90% of the particles of the expanded graphite have a particle size of at least 200 microns.

25. The process according to any one of clauses 17 to 24, further comprising, before passing the heat sink material through one or more openings on the electrical/electronic component, positioning an insert beneath the electrical/electronic component, wherein the insert comprises holes configured to allow the heat sink material to pass therethrough and secure the insert to the heat sink material.

26. The process according to clause 25, wherein the heat sink surrounds at least a bottom portion of the insert.

27. The process according to clause 25, wherein the holes on the insert align with the openings in the electric/electronic component so that the thermally conductive thermoplastic polymer of the heat sink secures the insert and the electric/electronic component to the heat sink.

28. The process according to any one of clause clauses 25 to 27, wherein the insert is substantially flat.

29. The process according to any one of clause clauses 25 to 28, wherein the insert comprises a thermally conductive metal or metal alloy, such as aluminum.

30. A method of making an electronic module having an integrated heat sink, the method comprising: inserting an electrical/electronic component into a mold; introducing a thermally conductive thermoplastic polymer composition into the mold so that the thermally conductive thermoplastic polymer passes through one or more openings on the electrical/electronic component and, optionally, partially or fully surrounds the electrical/electronic component; and cooling the thermally conductive thermoplastic polymer to form the electronic module with the integrated heat sink.

31. The method according to clause 30, wherein the thermally conductive thermoplastic polymer composition surrounds at least a bottom portion of the electrical/electronic component.

32. The method according to clause 30 or 31, wherein the mold includes cavities positioned above the openings on the electrical/electronic component so that the thermally conductive thermoplastic polymer composition forms caps over the openings.

33. The method according to any one of clauses 30 to 32, further comprising, before introducing the thermally conductive thermoplastic polymer composition into the mold, positioning an insert beneath the electric/electronic component in the mold, wherein the insert comprises holes configured to allow the thermally conductive thermoplastic polymer composition to pass therethrough and secure the insert to the electronic module with the integrated heat sink.

34. The method according to clause 33, wherein the holes on the insert align with the openings in the electric/electronic component so that the thermally conductive thermoplastic polymer passes therethrough to secure the insert to the electronic module with the integrated heat sink.

35. The method according to clause 33 or 34, wherein the thermally conductive thermoplastic polymer composition surrounds at least a bottom portion of the insert.

1. An electronic module comprising:
an electrical/electronic component comprising openings;
a heat sink comprising a thermally conductive thermoplastic polymer composition,
wherein the heat sink passes through one or more of the openings on the electrical/electronic component, and optionally partially or fully surrounds the electrical/electronic component, to form the electronic module.

2. The electronic module of claim 1, wherein the heat sink surrounds at least a bottom portion of the electrical/electronic component.

3. The electronic module of claim 1, wherein the electrical/electronic component comprises a printed circuit board, and the openings comprise attachment openings, VIA holes, through-holes, or a combination thereof in the printed circuit board.

4. The electronic module of claim 3, wherein the printed circuit board has a thickness of greater than 50 microns (0.05 millimeters).

5. The electronic module of claim 3, wherein the printed circuit board has a thickness of greater than 500 microns (0.5 millimeters).

6. The electronic module of claim 1, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers

7. The electronic module of claim 1, wherein the thermally conductive thermoplastic polymer composition comprises expanded graphite in an amount of from 10 wt.-% to 70 wt.-% of the composition.

8. The electronic module of claim 1, wherein the thermally conductive thermoplastic polymer composition comprises expanded graphite in an amount of from 20 wt.-% to 60 wt.-% of the composition.

9. The electronic module of claim 1, wherein the thermally conductive thermoplastic polymer composition comprises expanded graphite in an amount of from 30 wt.-% to 50 wt.-% of the composition.

10. The electronic module of claim 7, wherein at least 90% of the particles of the expanded graphite have a particle size of at least 200 microns.

11. The electronic module of claim 1, wherein the heat sink comprises linearly extending fins.

12. The electronic module of claim 1, further comprising an insert positioned between the electrical/electronic component and the heat sink.

13. The electronic module of claim 12, wherein the heat sink surrounds at least a bottom portion of the insert.

14. The electronic module of claim 12, wherein the insert is substantially flat.

15. The electronic module of claim 12, wherein the insert comprises holes for the thermally conductive thermoplastic polymer of the heat sink to pass through to secure the heat sink to the insert.

16. The electronic module of claim 15, wherein the holes in the heat sink align with the openings in the electric/electronic component so that the thermally conductive thermoplastic polymer of the heat sink secures the insert and the electric/electronic component to the heat sink.

17. The electronic module of claim 12, wherein the insert comprises a thermally conductive metal or metal alloy.

18. The electronic module of claim 17, wherein the insert comprises aluminum.

19.-38. (canceled)
